(19) United States
(12) Patent Application Publication
(10) Pub. No.: US 2026/0075957 A1
(43) Pub. Date: Mar. 12, 2026

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Mika ADACHI, Himeji Hyogo (JP); Masaru FURUKAWA, Himeji Hyogo (JP)

(21) Appl. No.: 19/063,899

(22) Filed: Feb. 26, 2025

(30) Foreign Application Priority Data
Sep. 6, 2024 (JP) 2024-154011

(51) Int. Cl. H10D 89/60

(52) U.S. Cl. CPC H10D 89/611; H10D 89/931

(57) ABSTRACT

According to one embodiment, a semiconductor device includes a semiconductor layer and a diode. The diode is provided on an outer peripheral region of the semiconductor layer via an insulating layer. The diode includes a first semiconductor region of a first conductivity type and a second semiconductor region of a second conductivity type. The first semiconductor region including a first extending portion that extends in a first direction and multiple first protruding portions that protrude from the first extending portion in a second direction. The second semiconductor region includes a second extending portion that extends in the first direction and multiple second protruding portions that protrude from the second extending portion in the second direction. The first protruding portions and the second protruding portions alternate in the first direction.

### CROSS-REFERENCE TO RELATED APPLICATIONS

This application is based upon and claims the benefit of priority from Japanese Patent Application No. 2024-154011, filed on Sep. 6, 2024; the entire contents of which are incorporated herein by reference.

### FIELD

Embodiments of the present invention generally relate to a semiconductor device.

### BACKGROUND

There are semiconductor devices in which diodes are built-in. For this semiconductor device, a technology that enables miniaturization of the diode is required.

### BRIEF DESCRIPTION OF THE DRAWINGS

FIG. 1 is a plan view illustrating a semiconductor device according to an embodiment;

FIG. 2 is an enlarged plan view of a portion II in FIG. 1;

FIG. 3 is a III-III cross-sectional view in FIG. 2;

FIG. 4A is a plan view illustrating a diode in a semiconductor device according to a reference example, and FIG. 4B is a graph schematically showing electric field strength on a B-B line in FIG. 4A;

FIG. 5A is a plan view illustrating a diode in the semiconductor device according to the embodiment, and FIG. 5B is a graph schematically showing electric field strength on a B-B line in FIG. 5A;

FIG. 6 is a plan view illustrating the diode in the semiconductor device according to the embodiment;

FIG. 7 is a plan view illustrating a portion of a semiconductor device according to a modification of the embodiment;

FIG. 8A is a plan view illustrating a semiconductor device according to an example, and FIG. 8B is a bottom view illustrating the semiconductor device according to the example;

FIG. 9 is an electrical circuit diagram of the semiconductor device according to the example;

FIG. 10 is an enlarged plan view of a cathode electrode in FIG. 8A; and

FIG. 11A is an enlarged plan view of a portion XA in FIG. 10, and FIG. 11B is an enlarged plan view of a portion XB in FIG. 10.

### DETAILED DESCRIPTION

According to one embodiment, a semiconductor device includes a semiconductor layer and a diode. The semiconductor layer includes an element region where a semiconductor element is provided and an outer peripheral region located around the element region along a first plane. The diode is provided on the outer peripheral region via an insulating layer and contains polysilicon. The diode includes a first semiconductor region of a first conductivity type and a second semiconductor region of a second conductivity type. The first semiconductor region includes a first extending portion that extends in a first direction parallel to the first plane and a plurality of first protruding portions that protrude from the first extending portion in a second direction. The second direction is perpendicular to the first direction and parallel to the first plane. The second semiconductor region includes a second extending portion that extends in the first direction and a plurality of second protruding portions that protrude from the second extending portion in the second direction. The plurality of first protruding portions and the plurality of second protruding portions alternate in the first direction.

Embodiments of the invention will now be described with reference to the drawings. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated. In the drawings and the specification of the application, components similar to those described thereinabove are marked with like reference numerals, and a detailed description is omitted as appropriate.

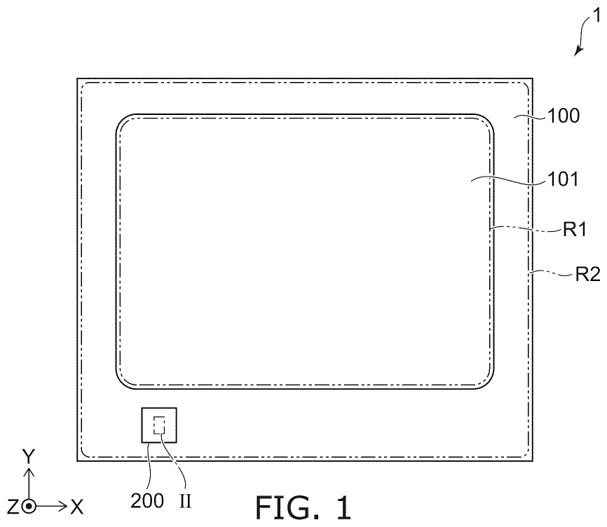

FIG. 1 is a plan view illustrating a semiconductor device according to an embodiment. As shown in FIG. 1, the semiconductor device 1 according to the embodiment includes a semiconductor layer 100 and a diode 200.

An XYZ orthogonal coordinate system is used in the description of the embodiments. Two mutually-orthogonal directions parallel to a front surface of the semiconductor layer 100 are taken as an X-direction (an example of a first direction) and a Y-direction (an example of a second direction). A direction perpendicular to the X-direction and the Y-direction is taken as a Z-direction. In the description, the direction from one surface of the semiconductor layer 100 toward the other surface is called “up/upward/above”, and the opposite direction is called “down/downward/below”. These directions are independent of the direction of gravity.

The semiconductor layer 100 includes an element region R1 and an outer peripheral region R2. In the drawings, the element region R1 and the outer peripheral region R2 are shown by two-dot chain lines. A semiconductor element is provided in the element region R1. The semiconductor element is a Metal Oxide Semiconductor Field Effect Transistor (MOSFET) or an Insulated Gate Bipolar Transistor (IGBT). The semiconductor element may be a vertical-type element with electrodes provided on the upper surface and the lower surface of the semiconductor layer. Alternatively, the semiconductor element may be a lateral-type element in which an electrode is provided only on the upper surface of the semiconductor layer.

In the illustrated example, the element region R1 includes a vertical-type MOSFET or IGBT. An upper electrode 101 (a first electrode) electrically connected to the semiconductor element is provided on the element region R1. A lower electrode (not shown) electrically connected to the semiconductor element is provided under the element region R1.

The outer peripheral region R2 is located around the element region R1 in the X-Y plane (a first plane). The diode 200 is provided on the outer peripheral region R2. The diode 200 may be electrically connected to the semiconductor element or may be electrically isolated from the semiconductor element.

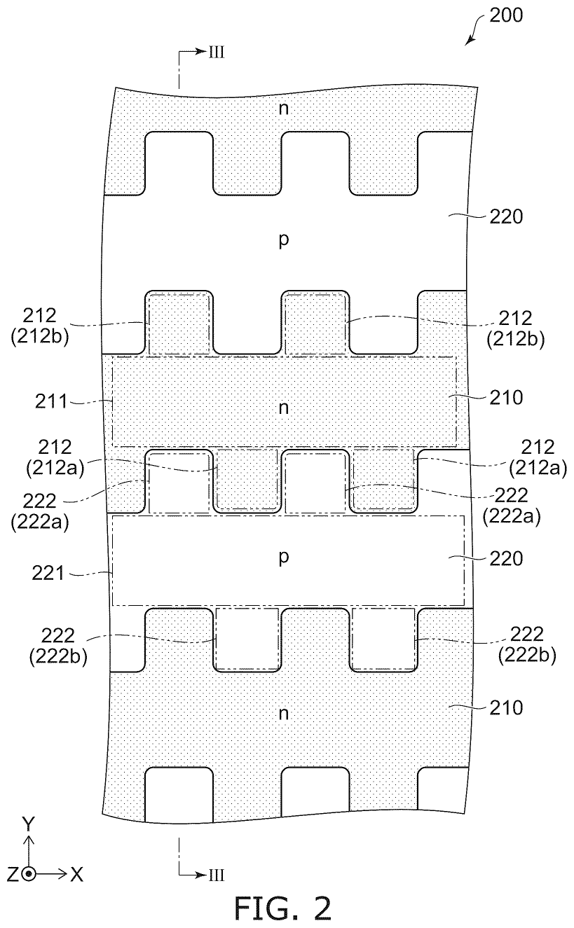

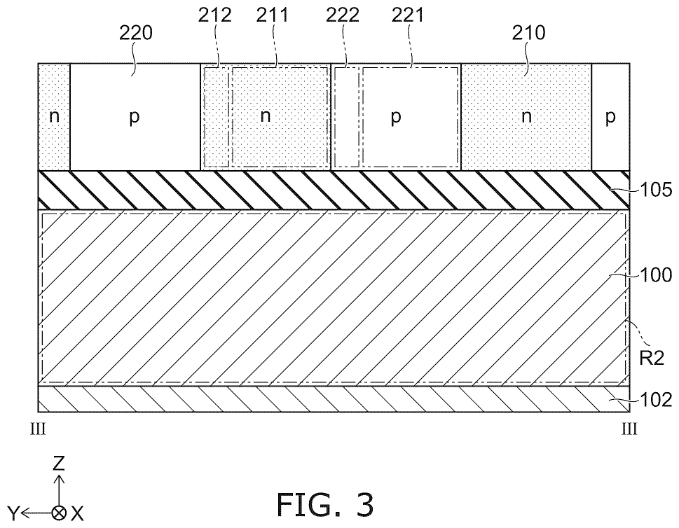

FIG. 2 is an enlarged plan view of a portion II in FIG. 1. FIG. 3 is a III-III cross-sectional view in FIG. 2.

As shown in FIG. 2, the diode 200 includes a first semiconductor region 210 and a second semiconductor region 220. The first semiconductor region 210 has one of the conductivity types, either n-type or p-type. The second semiconductor region 220 has the other conductivity type. In the illustrated example, the conductivity type of the first semiconductor region 210 is an n-type (an example of a first conductivity type), and the conductivity type of the second semiconductor region 220 is a p-type (an example of a second conductivity type).

The first semiconductor region 210 and the second semiconductor region 220 are in contact with each other, and a p-n junction is formed between the first semiconductor region 210 and the second semiconductor region 220. As shown in FIG. 3, the first semiconductor region 210 and the second semiconductor region 220 are provided on the semiconductor layer 100 via an insulating layer 105. A lower electrode 102 (a second electrode) electrically connected to the semiconductor element of the element region R1 is provided under the semiconductor layer 100. As shown in FIG. 3, the lower electrode 102 may be provided not only in the area under the element region R1 but also in the area under the outer peripheral region R2.

As shown in FIG. 2, the first semiconductor region 210 includes a first extending portion 211 and multiple first protruding portions 212. In FIG. 2, the first extending portion 211 and the first protruding portions 212 are shown by two-dot chain lines. The first extending portion 211 extends in the X-direction. In other words, the length of the first extending portion 211 in the X-direction is longer than the length of the first extending portion 211 in the Y-direction. The multiple first protruding portions 212 are separated from each other in the X-direction. Each first protruding portion 212 protrudes from the first extending portion 211 in the Y-direction.

The second semiconductor region 220 includes a second extending portion 221 and multiple second protruding portions 222. In the drawings, the second extending portion 221 and the second protruding portions 222 are shown by two-dot chain lines. The second extending portion 221 extends in the X-direction. The multiple second protruding portions 222 are separated from each other in the X-direction. Each second protruding portion 222 protrudes from the second extending portion 221 in the Y-direction. The multiple first protruding portions 212 and the multiple second protruding portions 222 alternate in the X-direction.

As shown in FIGS. 2 and 3, the first semiconductor region 210 and the second semiconductor region 220 may be provided alternately in the Y-direction. In such a case, the first semiconductor region 210 includes multiple first protruding portions 212a and multiple first protruding portions 212b. The multiple first protruding portions 212a protrude on one side of the first semiconductor region 210 in the Y-direction. The multiple first protruding portions 212b protrude on the other side of the first semiconductor region 210 in the Y-direction. The first extending portion 211 is positioned between the multiple first protruding portions 212a and the multiple first protruding portions 212b.

Similarly, the second semiconductor region 220 includes multiple second protruding portions 222a and multiple second protruding portions 222b. The multiple second protruding portions 222a protrude on one side of the second semiconductor region 220 in the Y-direction. The multiple second protruding portions 222b protrude on the other side of the second semiconductor region 220 in the Y-direction. The second extending portion 221 is positioned between the multiple second protruding portions 222a and the multiple second protruding portions 222b.

The position in the X-direction of each first protruding portion 212a is different from the position in the X-direction of each first protruding portion 212b. When viewed from the Y-direction, the first protruding portions 212a and the first protruding portions 212b alternate in the X-direction. Similarly, the position in the X-direction of each second protruding portion 222a is different from the position in the X-direction of each second protruding portion 222b. When viewed from the Y-direction, the second protruding portions 222a and the second protruding portions 222b alternate in the X-direction.

The semiconductor layer 100 includes a semiconductor material such as silicon, silicon carbide, or gallium nitride. The upper electrode 101 includes a metal material such as aluminum, titanium, or tungsten. The insulating layer 105 includes an insulating material such as silicon oxide or silicon nitride. The first semiconductor region 210 and the second semiconductor region 220 include polysilicon. As an n-type impurity, arsenic, phosphorus, antimony, or the like is used. As a p-type impurity, boron or aluminum is used. The first semiconductor region 210 and the second semiconductor region 220 can be formed by ion implantation of n-type impurities and p-type impurities, respectively, into a polysilicon layer.

The n-type impurity concentration in the first semiconductor region 210 may be the same as the p-type impurity concentration in the second semiconductor region 220, or may be different from the p-type impurity concentration in the second semiconductor region 220. For example, p-type impurities are ion-implanted into the entire surface of the region where the diode 200 is formed, and then n-type impurities are ion-implanted into a portion of the region. In such a case, the n-type impurity concentration in the first semiconductor region 210 is greater than the p-type impurity concentration in the second semiconductor region 220. For example, the n-type impurity concentration in the first semiconductor region 210 is not less than 6.0×10¹⁴ cm⁻³ and not more than 3.0×10¹⁶ cm⁻³. The p-type impurity concentration in the second semiconductor region 220 is not less than 1.0×10¹⁴ cm⁻³, and not more than 7.0×10¹⁵ cm⁻³.

Advantages of the embodiment will now be described.

A diode may be integrated in a semiconductor device. For example, as shown in FIG. 1, a semiconductor element such as a MOSFET or an IGBT is provided in the element region R1, and the diode 200 is provided on the outer peripheral region R2. In such a case, the outer peripheral region R2 is an inactive region that does not directly contribute to the operation of the semiconductor element. For miniaturization of the semiconductor device, it is preferable that the inactive region is small. In order to reduce the size of the inactive region, the diode 200 is preferably small.

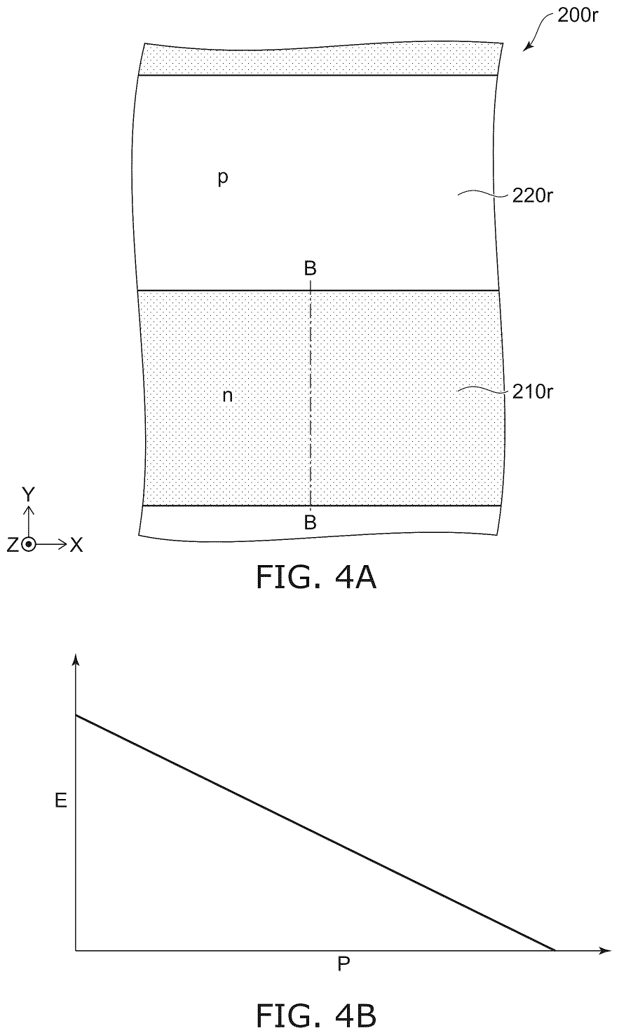

FIG. 4A is a plan view illustrating a diode in a semiconductor device according to a reference example. FIG. 4B is a graph schematically showing electric field strength on a B-B line in FIG. 4A.

In a diode 200r shown in FIG. 4A, the first semiconductor region 210r and the second semiconductor region 220r extend in the X-direction. The first semiconductor region 210r and the second semiconductor region 220r do not include portions protruding in the Y-direction. The p-n junction between the first semiconductor region 210r and the second semiconductor region 220r is parallel to the X-direction.

When a reverse voltage is applied to the diode 200r, the depletion layer spreads in the Y-direction from the p-n junction between the first semiconductor region 210r and the second semiconductor region 220r. The electric field strength at this time is as shown in FIG. 4B. In FIG. 4B, the horizontal axis represents the position P in the Y-direction, and the vertical axis represents the electric field strength E. In the diode 200r according to the reference example, the electric field strength E decreases as the distance from the p-n junction increases.

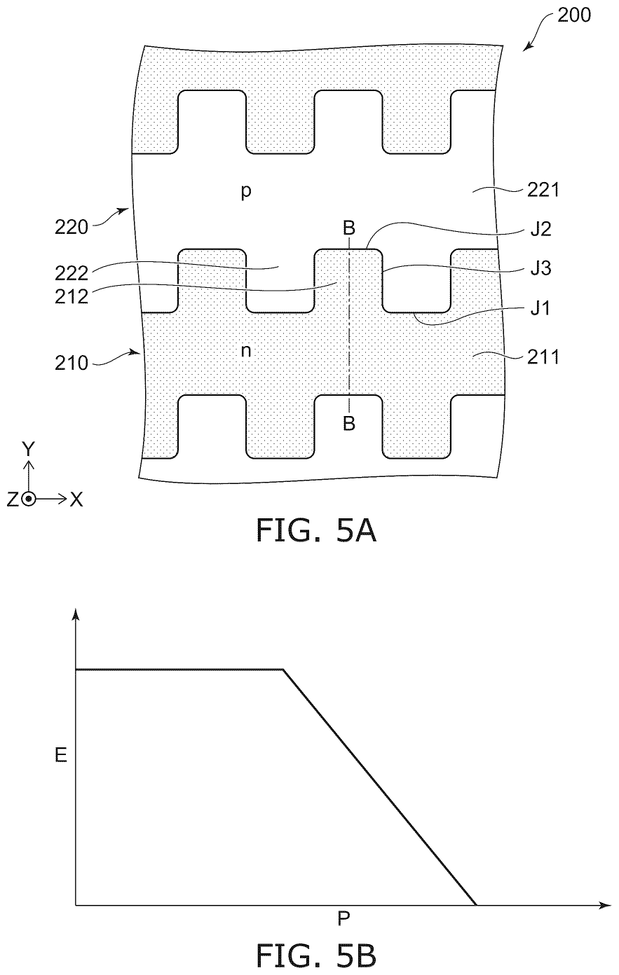

FIG. 5A is a plan view illustrating the diode in the semiconductor device according to the embodiment. FIG. 5B is a graph schematically showing the electric field strength on a B-B line in FIG. 5A.

In the embodiment, the first semiconductor region 210 includes multiple first protruding portions 212, and the second semiconductor region 220 includes the multiple second protruding portions 222. The multiple first protruding portions 212 and the multiple second protruding portions 222 alternate in the X-direction. The diode 200 includes a p-n junction J1 between the first extending portion 211 and the second protruding portion 222, a p-n junction J2 between the first protruding portion 212 and the second extending portion 221, and a p-n junction J3 between the first protruding portion 212 and the second protruding portion 222.

When a reverse voltage is applied to the diode 200, the depletion layer spreads in the Y-direction from the p-n junctions J1 and J2, and the depletion layer spreads in the X-direction from the p-n junction J3. The electric field strength at this time is as shown in FIG. 5B. In FIG. 5B, the horizontal axis represents the position P in the Y-direction, and the vertical axis represents the electric field strength E. According to the diode 200, the spread of the depletion layer in the X-direction from the p-n junction J3 enables the electric field strength in the first protruding portion 212 to remain substantially constant in the Y-direction.

The breakdown voltage is represented by a value obtained by integrating the electric field strength E over the position P. In the semiconductor device according to the reference example, the electric field strength E in the diode decreases as the distance from the p-n junction increases. On the other hand, in the semiconductor device according to the embodiment, the electric field strength in the first protruding portion 212 and the electric field strength in the second protruding portion 222 are substantially constant in the Y-direction. The breakdown voltage of the diode 200 can be increased in proportion to the improvement in these electric field strengths.

When the area of the diode is the same, according to the embodiment, the breakdown voltage of the diode can be increased compared to the reference example. Alternatively, according to the embodiment, the area of the diode required to achieve a specific breakdown voltage can be reduced compared to the reference example. As a result, the inactive region in the semiconductor device 1 can be reduced, and the semiconductor device 1 can be miniaturized.

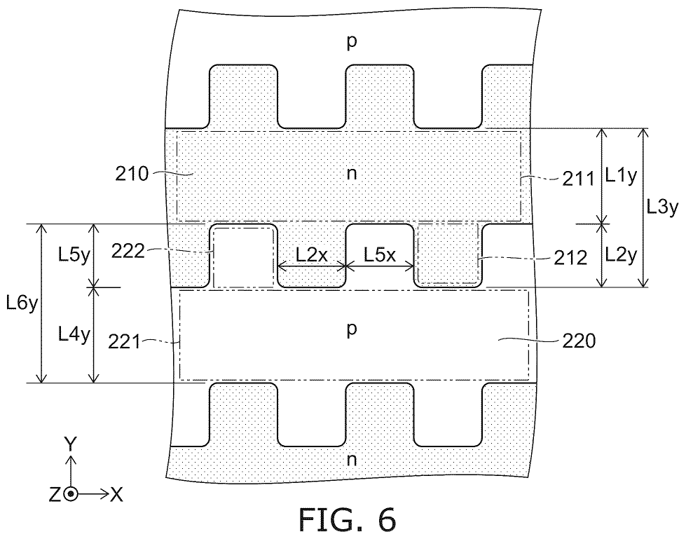

FIG. 6 is a plan view illustrating the diode in the semiconductor device according to the embodiment.

With reference to FIG. 6, a preferred structure of the embodiment will now be described. The length of the first extending portion 211 in the Y-direction is taken as “L1y”. The length of one first protruding portion 212 in the Y-direction is taken as “L2y”. The sum of the lengths L1y and L2y is taken as “L3y”. For example, the ratio (L2y/L3y) of the length L2y to the sum L3y is not less than 0.1 and not more than 0.9. The larger the ratio (L2y/L3y), the greater the proportion of the portion with high electric field strength, and the higher the breakdown voltage of the diode 200. Therefore, the ratio (L2y/L3y) is preferably not less than 0.2, more preferably not less than 0.3. On the other hand, if the ratio (L2y/L3y) is excessively large, the forward voltage Vf increases. Therefore, the ratio (L2y/L3y) is preferably not more than 0.8, more preferably not more than 0.7.

Similarly, the length of the second extending portion 221 in the Y-direction is taken as “L4y”. The length of one second protruding portion 222 in the Y-direction is taken as “L5y”. The sum of the lengths L4y and L5y is taken as “L6y”. The ratio (L5y/L6y) of the length L5y to the length L6y is, for example, not less than 0.1 and not more than 0.9. From the viewpoint of improving the breakdown voltage, the ratio (L5y/L6y) is preferably not less than 0.2, more preferably not less than 0.3. In order to suppress the increase in the forward voltage Vf, the ratio (L5y/L6y) is preferably not more than 0.8, more preferably not more than 0.7.

Specifically, the length L2y and length L5y are designed to be not less than 0.2 μm. From the viewpoint of improving the breakdown voltage, the length L2y and the length L5y are preferably not less than 0.5 μm, and more preferably not less than 1.0 μm.

The ratio (L5x/L2x) of the length L5x in the X-direction of one second protruding portion 222 to the length L2x in the X-direction of one first protruding portion 212 is not less than 0.1 and not more than 10. It is preferable that the difference between the effective n-type impurity concentration in the first semiconductor region 210 and the effective p-type impurity concentration in the second semiconductor region 220 be small, and more preferably, that they be substantially the same. “Effective impurity concentration” refers to the impurity concentration after compensation when a region includes both n-type and p-type impurities. When one region includes either an n-type impurity or a p-type impurity, the n-type impurity concentration or the p-type impurity concentration can be regarded as the effective impurity concentration. When the difference between the effective n-type impurity concentration in the first semiconductor region 210 and the effective p-type impurity concentration in the second semiconductor region 220 is small, it is preferable for the ratio (L5x/L2x) to be closer to 1. Therefore, the ratio (L5x/L2x) is preferably not less than 0.2 and not more than 9, and more preferably not less than 0.3 and not more than 8.

The ratio (L2y/L2x) of the length L2y in the Y-direction of one first protruding portion 212 to the length L2x in the X-direction of one first protruding portion 212 is, for example, not less than 0.1 and not more than 10. The shorter the length L2x, the greater the number of first protruding portions 212 per unit area, and the higher the breakdown voltage of the diode 200. In addition, the longer the length L2y, the greater the proportion of the portion with high electric field strength, and the breakdown voltage of the diode 200 can be improved. Therefore, the ratio (L2y/L2x) is preferably not less than 0.2, more preferably not less than 0.3. On the other hand, if the ratio (L2y/L2x) is excessively large, the forward voltage Vf increases. Therefore, the ratio (L2y/L2x) is preferably not more than 9, more preferably not more than 8.

Similarly, the ratio (L5y/L5x) of the length L5y in the Y-direction of one second protruding portion 222 to the length L5x in the X-direction of one second protruding portion 222 is, for example, not less than 0.1 and not more than 10. From the viewpoint of improving the breakdown voltage, the ratio (L5y/L5x) is preferably not less than 0.2, more preferably not less than 0.3. Further, in order to suppress the increase in the forward voltage Vf, the ratio (L5y/L5x) is preferably not more than 9, more preferably not more than 8.

The embodiment of the present invention is particularly suitable for a semiconductor device 1 in which a semiconductor layer 100 of silicon carbide is used. The semiconductor layer 100 of silicon carbide is very costly compared to silicon or gallium nitride. According to the embodiment, the diode 200 can be miniaturized, and the size of the outer peripheral region R2 can be decreased. By decreasing the size of the outer peripheral region R2, the size of the semiconductor layer 100 can be decreased. As a result, the cost of the semiconductor device 1 can be reduced.

### Modification

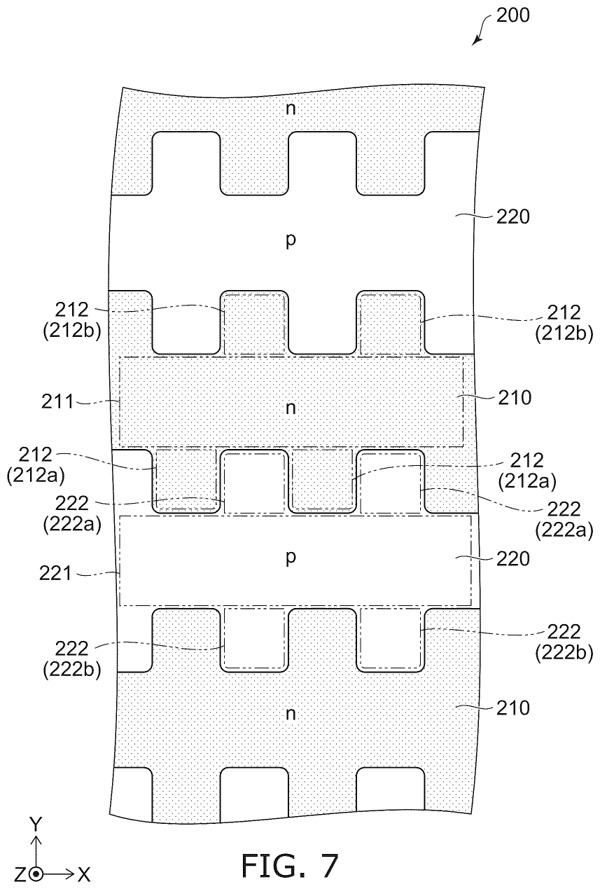

FIG. 7 is a plan view illustrating a portion of a semiconductor device according to a modification of the embodiment.

In the example shown in FIGS. 2 and 6, the position in the X-direction of the first protruding portion 212a is different from the position in the X-direction of the first protruding portion 212b. The position in the X-direction of the second protruding portion 222a is different from the position in the X-direction of the second protruding portion 222b. In the example shown in FIG. 7, the position in the X-direction of the first protruding portion 212a is the same as the position in the X-direction of the first protruding portion 212b. In addition, the position in the X-direction of the second protruding portion 222a is the same as the position in the X-direction of the second protruding portion 222b. Thus, the positional relationship between the first protruding portion 212a and the first protruding portion 212b, and the positional relationship between the second protruding portion 222a and the second protruding portion 222b can be changed as needed.

### EXAMPLE

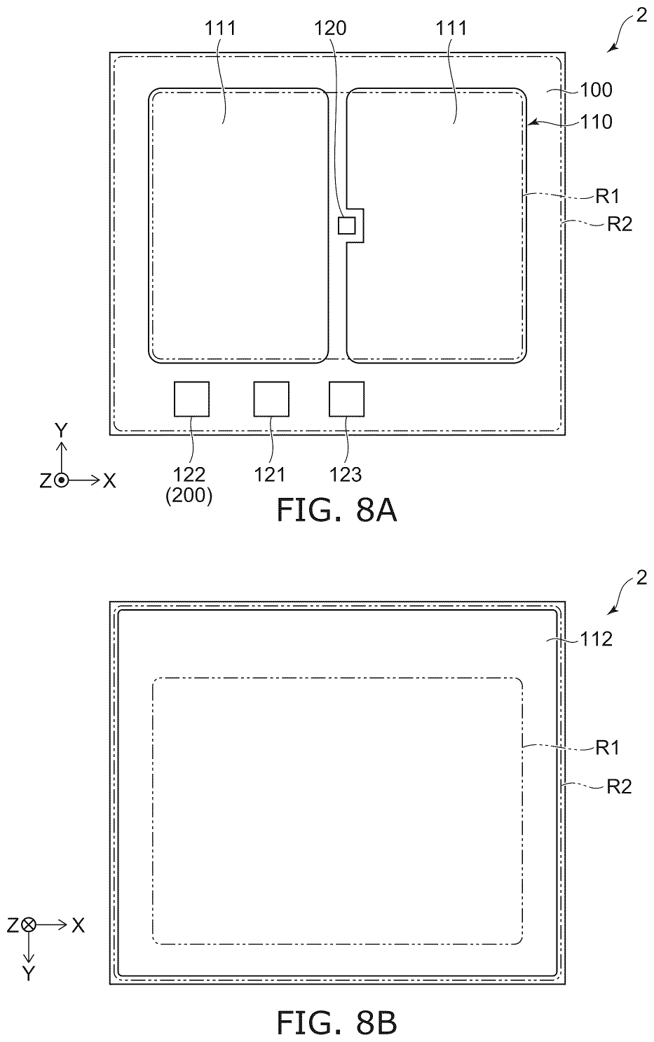

FIG. 8A is a plan view illustrating a semiconductor device according to an example. FIG. 8B is a bottom view illustrating the semiconductor device according to the example.

The semiconductor device 2 according to the example includes an IGBT 110 as the semiconductor element. As shown in FIG. 8A, multiple emitter electrodes 111 are provided on the upper surface of the semiconductor layer 100 in the element region R1. As shown in FIG. 8B, a collector electrode 112 is provided on the lower surface of the semiconductor layer 100 in the element region R1 and the outer peripheral region R2.

A sense diode 120 is further provided on the element region R1. The sense diode 120 is used to measure temperature. The sense diode 120 is positioned between the emitter electrodes 111.

An anode electrode 121, a cathode electrode 122, and a gate pad 123 are provided on the outer peripheral region R2. The anode electrode 121, the cathode electrode 122, and the gate pad 123 are separated from each other.

The anode electrode 121 is electrically connected to the anode side of the sense diode 120, and the cathode electrode 122 is electrically connected to the cathode side of the sense diode 120. Additionally, in the semiconductor device 2, the diode 200 is provided at the same location as the cathode electrode 122. The gate pad 123 is electrically connected to the gate electrode of the IGBT 110.

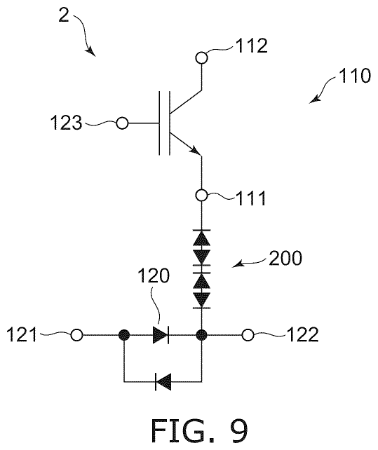

FIG. 9 is an electrical circuit diagram of the semiconductor device according to the example.

As shown in FIG. 9, in the semiconductor device 2, the diode 200 is connected between the emitter electrode 111 of the IGBT 110 and the cathode side of the sense diode 120. The diode 200 functions as a Zener diode.

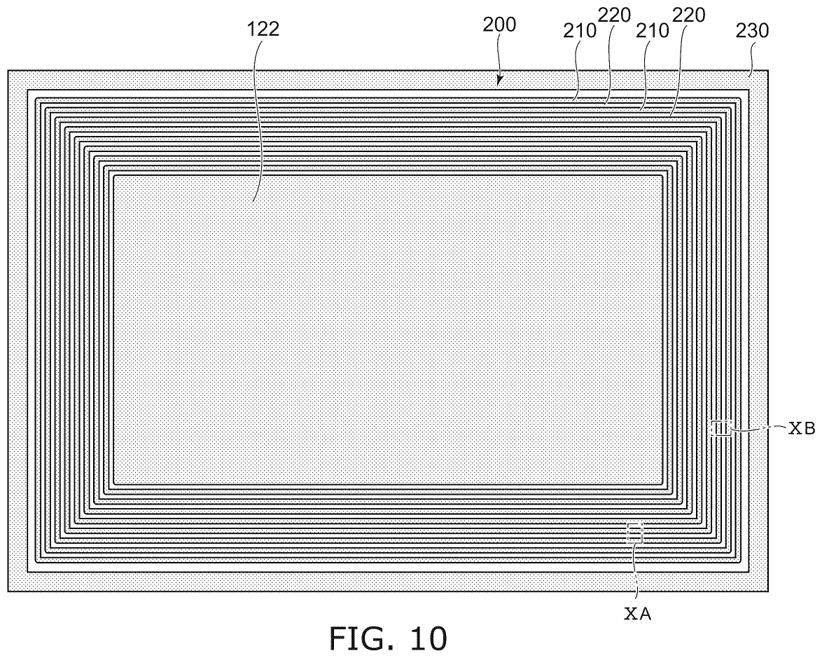

FIG. 10 is an enlarged plan view of the cathode electrode in FIG. 8A.

As shown in FIG. 10, the first semiconductor region 210 and the second semiconductor region 220 are provided along the outer periphery of the cathode electrode 122. The first semiconductor region 210 and the second semiconductor region 220 are alternately arranged in a direction away from the cathode electrode 122. By providing the first semiconductor region 210 and the second semiconductor region 220 around the cathode electrode 122, the area of the p-n junction between the first semiconductor region 210 and the second semiconductor region 220 can be increased. An electrode layer 230 electrically connected to the emitter electrode 111 is provided on the outer periphery of the multiple first semiconductor regions 210 and multiple second semiconductor regions 220.

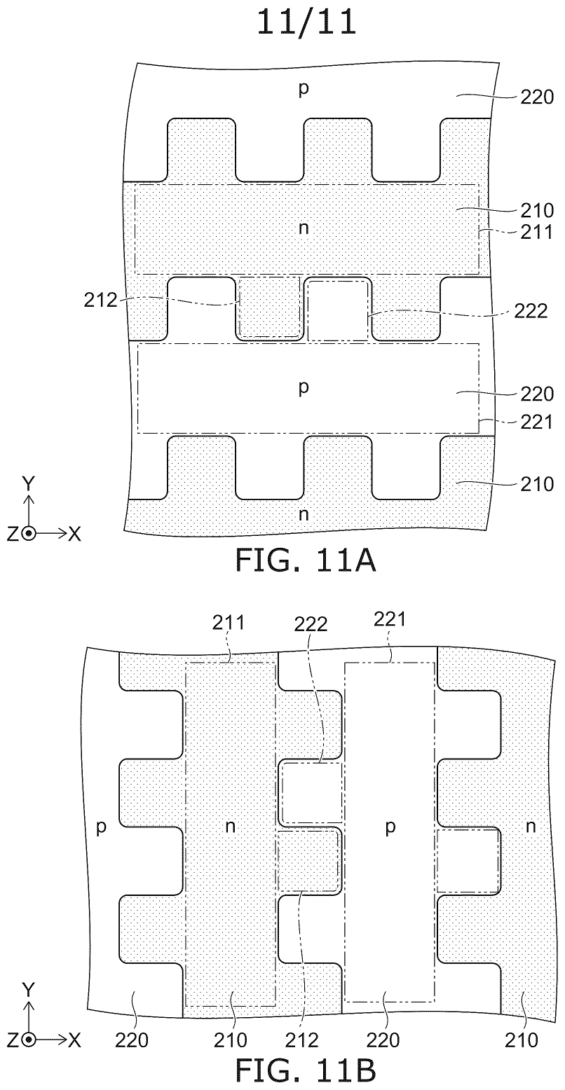

FIG. 11A is an enlarged plan view of a portion XA in FIG. 10. FIG. 11B is an enlarged plan view of a portion XB in FIG. 10.

In the portion XA, as shown in FIG. 11A, the first extending portion 211 and the second extending portion 221 extend in the X-direction. The first protruding portion 212 protrudes from the first extending portion 211 in the Y-direction, and the second protruding portion 222 protrudes from the second extending portion 221 in the Y-direction.

In the portion XB, as shown in FIG. 11B, the first extending portion 211 and the second extending portion 221 extend in the Y-direction. The first protruding portion 212 protrudes from the first extending portion 211 in the X-direction, and the second protruding portion 222 protrudes from the second extending portion 221 in the X-direction.

As shown in FIGS. 11A and 11B, each part of both the first semiconductor region 210 and the second semiconductor region 220 includes an extending portion that extends in one direction and a protruding portion that protrudes in the orthogonal direction from the extending portion. As a result, the breakdown voltage of the diode 200 can be improved. Alternatively, the area of the diode 200 can be reduced while maintaining the breakdown voltage of the diode 200. In the example, instead of the structure shown in FIGS. 10A and 10B, the structure of the modification shown in FIG. 7 may be applied.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Moreover, above-mentioned embodiments can be combined mutually and can be carried out.

What is claimed is:

1. A semiconductor device, comprising:
a semiconductor layer including
an element region where a semiconductor element is provided, and
an outer peripheral region located around the element region along a first plane;
a diode provided on the outer peripheral region via an insulating layer and containing polysilicon, the diode including a first semiconductor region of a first conductivity type and a second semiconductor region of a second conductivity type,
the first semiconductor region including
a first extending portion that extends in a first direction parallel to the first plane, and
a plurality of first protruding portions that protrude from the first extending portion in a second direction, the second direction being perpendicular to the first direction and parallel to the first plane,
the second semiconductor region including
a second extending portion that extends in the first direction, and
a plurality of second protruding portions that protrude from the second extending portion in the second direction,
the plurality of first protruding portions and the plurality of second protruding portions alternating in the first direction.

2. The semiconductor device according to claim 1, wherein
the first semiconductor region and the second semiconductor region are alternately provided in the second direction.

3. The semiconductor device according to claim 1, wherein
a ratio of a length of one of the plurality of first protruding portions in the second direction to a sum of a length in the second direction of the first extending portion and the length of the one of the plurality of first protruding portions is not less than 0.1 and not more than 0.9.

4. The semiconductor device according to claim 3, wherein the ratio is not less than 0.3 and not more than 0.7.

5. The semiconductor device according to claim 1, wherein
a ratio of a length of one of the plurality of second protruding portions in the first direction to a length of one of the plurality of first protruding portions in the first direction is not less than 0.1 and not more than 10.

6. The semiconductor device according to claim 5, wherein the ratio is not less than 0.3 and not more than 8.

7. The semiconductor device according to claim 1, wherein
a ratio of a length of one of the plurality of first protruding portions in the second direction to a length of the one of the plurality of first protruding portions in the first direction is not less than 0.1 and not more than 10.

8. The semiconductor device according to claim 7, wherein the ratio is not less than 0.3 and not more than 8.

9. The semiconductor device according to claim 1, wherein
a length of one of the plurality of first protruding portions in the second direction and a length of one of the plurality of second protruding portions in the second direction are not less than 0.2 μm.

10. The semiconductor device according to claim 1, wherein
a length of one of the plurality of first protruding portions in the second direction and a length of one of the plurality of second protruding portions in the second direction are not less than 1.0 μm.

11. The semiconductor device according to claim 1, wherein
the first semiconductor region includes another plurality of first protruding portions that protrude from the first extending portion in the second direction,
the first extending portion is located between the plurality of first protruding portions and the other plurality of first protruding portions,
the second semiconductor region includes another plurality of second protruding portions that protrude from the second extending portion in the second direction, and
the second extending portion is located between the plurality of second protruding portions and the other plurality of second protruding portions.

12. The semiconductor device according to claim 1, wherein the semiconductor element includes a MOSFET or an IGBT.

13. The semiconductor device according to claim 12, further comprising an electrode provided on the outer peripheral region via the insulating layer,
the diode being electrically connected between the semiconductor element and the electrode.

14. The semiconductor device according to claim 13, wherein
the first semiconductor region and the second semiconductor region are provided around the electrode along the first plane.

15. The semiconductor device according to claim 14, wherein
the first semiconductor region and the second semiconductor region are alternately provided in a direction away from the electrode.

16. The semiconductor device according to claim 1, further comprising a first electrode provided on the element region.

17. The semiconductor device according to claim 16, further comprising a second electrode provided under the element region.

18. The semiconductor device according to claim 17, wherein
the second electrode is further provided under the outer peripheral region.

19. The semiconductor device according to claim 1, wherein
an impurity concentration of the first conductivity type in the first semiconductor region is not less than 6.0×10¹⁴ cm⁻³ and not more than 3.0×10¹⁶ cm⁻³, and
an impurity concentration of the second conductivity type in the second semiconductor region is not less than 1.0×10¹⁴ cm⁻³ and not more than 7.0×10¹⁵ cm⁻³.

20. The semiconductor device according to claim 1, wherein
the semiconductor layer contains silicon carbide.
